(19) United States
(12) Patent Application Publication
(10) Pub. No.: US 2026/0033346 A1
(43) Pub. Date: Jan. 29, 2026

(54) LEAD-WIRE FRAME STRUCTURE FOR PACKAGING AND SENSOR PACKAGE STRUCTURE

(71) Applicant: NINGBO CRRC TIMES TRANSDUCER TECHNOLOGY CO., LTD, Ningbo (CN)

(72) Inventors: Yang LV, Ningbo (CN); Yanan SHI, Ningbo (CN); Juping LI, Ningbo (CN); Xiaowei HOU, Ningbo (CN); Hao JIANG, Ningbo (CN); Mingming WU, Ningbo (CN)

(73) Assignee: NINGBO CRRC TIMES TRANSDUCER TECHNOLOGY CO., LTD, Ningbo (CN)

(21) Appl. No.: 19/342,634

(22) Filed: Sep. 28, 2025

Related U.S. Application Data
(63) Continuation of application No. PCT/CN2023/132864, filed on Nov. 21, 2023.

(30) Foreign Application Priority Data
Apr. 23, 2023 (CN) 202310437436.6

(51) Int. Cl. H01L 23/495

(52) U.S. Cl. CPC H01L 23/49503; H01L 23/49544

(57) ABSTRACT

A lead-wire frame structure for packaging and a sensor package structure, which are applied to the field of sensor preparation. The lead-wire frame structure comprises: a bonding-pad component and a plurality of pin components, wherein the bonding-pad component is provided with an inward recess in a plane direction of a coplane which is formed by the bonding-pad component and the plurality of pin components. In the plane direction, arc-shaped packaging interfaces for offsetting stresses are formed in an aligned manner on an inner contour of the recess and an outer contour of the recess in the bonding-pad component. In the present application, the bonding-pad component is provided with the inward recess in the plane direction, and the aligned packaging interfaces of the inner contour of the recess and the outer contour of the recess arc designed to be of arc-shaped structures, which can offset internal and external stresses.

### CROSS-REFERENCE TO RELATED APPLICATIONS

The present application claims priority to Chinese Patent Application No. 202310437436.6, filed with the China National Intellectual Property Administration on Apr. 23, 2023 and entitled “LEAD-WIRE FRAME STRUCTURE FOR PACKAGING AND SENSOR PACKAGE STRUCTURE”, which is incorporated herein by reference in its entirety.

### TECHNICAL FIELD

The present application relates to the field of sensor preparation, and in particular, to a lead-wire frame structure for packaging and a sensor package structure.

### BACKGROUND

In the package structures for the lead-wire frames in the prior art, in the example of a structure using the molding body to package the pad and frame structure in the sensor, due to the difference in thermal expansion coefficients of the molding material and the metal frame, when the sensor is in an environment with changing temperature and humidity, the interface between the molding body and the metal frame is easily affected by stresses. Especially, stress accumulation is extremely likely to occur at the right-angle design between the molding body and the metal frame. Under the influence of the temperature increase and decrease environment, the interface between the molding body and the metal frame is repeatedly subjected to tensile stress and push stress, which may cause interface delamination or structural deformation, resulting in failure of the package body.

### SUMMARY

In view of this, the present application aims to provide a lead-wire frame structure for packaging and a sensor package structure, solving the problem that in the prior art, under the influence of a temperature increase and decrease environment, an interface between a molding body and a metal frame is easily affected by stresses, which causes interface delamination or structural deformation, thereby resulting in failure of a package body.

To solve the above technical problem, the present application provides a lead-wire frame structure for packaging, including:
a bonding-pad component and a plurality of pin components, where
the bonding-pad component is provided with an inward recess in a plane direction of a coplane which is formed by the bonding-pad component and the plurality of pin components; and
in the plane direction, arc-shaped packaging interfaces for offsetting stresses are formed in an aligned manner on an inner contour of the recess and an outer contour of the recess in the bonding-pad component.

Optionally, the bonding-pad component is disposed symmetrically in at least one direction in the plane direction.

Optionally, the recess penetrates through the bonding-pad component along a direction perpendicular to the plane direction.

Optionally, packaged regions of the plurality of pin components are provided with stress relief through holes along a direction perpendicular to the plane direction.

Optionally, arc-shaped packaging interfaces for offsetting stresses within the stress relief through holes are formed at end portions of the packaged regions of the plurality of pin components along the plane direction.

Optionally, widened protruding structures are formed, along a direction perpendicular to an extending direction of the pin components in the plane direction, at the stress relief through holes formed on the plurality of pin components.

Optionally, arc-shaped packaging interfaces for offsetting the stresses within the stress relief through holes are formed on the widened protruding structures along the plane direction.

Optionally, end portion packaged regions of the plurality of pin components are provided with micro-etching trenches for preventing intrusion of impurities along an extending direction of the pin components.

Optionally, the bonding-pad component is provided with at least one bonding-pad stress relief hole; and
the bonding-pad stress relief hole is formed symmetrically along a symmetrical center line of a bonding pad.

The present application further provides a sensor package structure, including:

the above lead-wire frame structure for packaging, a sensor chip, and a package body, where
the package body is used for packaging the lead-wire frame structure and the sensor chip.

It can be seen that the lead-wire frame structure for packaging provided by the present application includes a bonding-pad component and a plurality of pin components. The bonding-pad component is provided with an inward recess in a plane direction of a coplane which is formed by the bonding-pad component and the plurality of pin components. In the plane direction, arc-shaped packaging interfaces for offsetting stresses are formed in an aligned manner on two sides inside the recess and outside the recess in the bonding-pad component. In the present application, a bonding-pad component is provided with an inward recess in a plane direction, and aligned packaging interfaces of an inner contour of the recess and an outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product.

In addition, the present application further provides a sensor package structure, which also has the above beneficial effects.

### BRIEF DESCRIPTION OF THE DRAWINGS

To describe the technical solutions in the embodiments of the present application or in the prior art more clearly, the following briefly introduces the accompanying drawings required for describing the embodiments or the prior art. Apparently, the accompanying drawings in the following description are only the embodiments of the present application, and those of ordinary skill in the art may still derive other accompanying drawings from these accompanying drawings without creative efforts.

FIG. 1 is a schematic structural diagram of a lead-wire frame structure for packaging according to an embodiment of the present application;

FIG. 2 is a schematic structural diagram of another lead-wire frame structure for packaging according to an embodiment of the present application; and

FIG. 3 is a schematic diagram of a sensor package structure according to an embodiment of the present application.

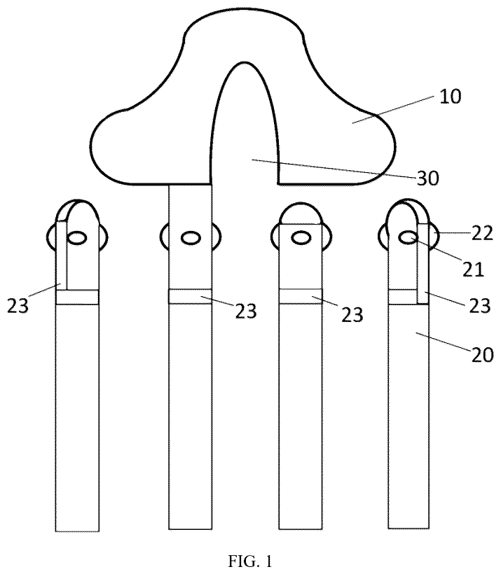

Reference numerals in FIG. 1 to FIG. 3 are as follows:
10. bonding-pad component, 11. bonding-pad stress relief hole;
20. pin component, 21. stress relief through hole, 22. widened protruding structure, 23. micro-etching trench;
30. recess;
40. package body;
50. sensor chip.

### DETAILED DESCRIPTION OF THE EMBODIMENTS

To make the objectives, technical solutions, and advantages of the embodiments of the present application clearer, the following clearly and completely describes the technical solutions in the embodiments of the present application with reference to the accompanying drawings in the embodiments of the present application. Apparently, the described embodiments are only some but not all of the embodiments of the present application. All other embodiments obtained by those of ordinary skill in the art based on the embodiments of the present application without creative efforts shall fall within the protection scope of the present application.

Currently, in a structure using a molding body to package a bonding pad and a frame structure in a sensor, due to a difference in thermal expansion coefficients of a molding material and a metal frame, when the sensor is in an environment with changing temperature and humidity, since a temperature in an external environment changes, the molding material and the metal frame generate stresses with different degrees of deformation trends. An interface between the molding body and the metal frame is easily affected by the stresses, especially, stress accumulation is extremely likely to occur at a right-angle design between the molding body and the metal frame. Therefore, the interface between the molding body and the metal frame is repeatedly subjected to a tensile stress and a push stress, which further causes interface delamination or structural deformation, thereby resulting in invalidation of the package body and reduction in the stability of a device.

In the present application, a bonding-pad component is provided with an inward recess in a plane direction, and aligned packaging interfaces of an inner contour of the recess and an outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product.

### Embodiment 1

Referring to FIG. 1, FIG. 1 is a schematic structural diagram of a lead-wire frame structure for packaging according to an embodiment of the present application. A packaged chip may include:
a bonding-pad component 10 and a plurality of pin components 20, where
the bonding-pad component 10 is provided with an inward recess 30 in a plane direction of a coplane which is formed by the bonding-pad component and the plurality of pin components 20; and
in the plane direction, arc-shaped packaging interfaces for offsetting stresses are formed in an aligned manner on an inner contour of the recess and an outer contour of the recess in the bonding-pad component 10.

In this embodiment, the bonding-pad component 10 and the plurality of pin components 20 form one coplane. In the plane, the bonding-pad component 10 is provided with the inward recess 30 at a specified position. Based on the inward recess 30, the arc-shaped inner contour of the recess and the arc-shaped outer contour of the recess are formed in the bonding-pad component 10, so that the offsetting stresses are formed in the aligned manner on the inner contour of the recess and the outer contour of the recess in the bonding-pad component 10. In this embodiment, the arc-shaped packaging interfaces for offsetting the stresses are formed in the aligned manner on the inner contour of the recess and the outer contour of the recess in the bonding-pad component 10. When various aligned interfaces on the inner contour of the recess and the outer contour of the recess in the bonding-pad component 10 are parallel to each other, a stress offsetting effect is best. In this embodiment, a size and a radian of a bonding pad may be adjusted through simulating optimization, to achieve aligned structures of offsetting the stresses of the inner contour of the recess and the outer contour of the recess.

A specific number of the pin components 20 is not limited in this embodiment, which may be set according to a specific application scenario as long as the number is greater than one. For example, there may be 2 pin components 20, or there may also be 3 pin components 20, or there may further be 4 pin components 20. A specific number of the inward recesses 30 formed in the bonding-pad component 10 is not limited in this embodiment. For example, there may be 1 inward recess 30 formed in the bonding-pad component 10, or there may also be 2 inward recesses 30 formed in the bonding-pad component 10, or there may further be 3 inward recesses 30 formed in the bonding-pad component 10. A position of the inward recess 30 formed in the bonding-pad component 10 is not limited in this embodiment. For example, the bonding-pad component 10 may be provided with the inward recess 30 at an edge position along the plane direction, or the bonding-pad component 10 may also be provided with the inward recess 30 at other positions. Specific formed radians of the arc-shaped inner contour of the recess and the arc-shaped outer contour of the recess are not limited in this embodiment as long as the aligned stresses between the inner and outer contours can be offset, which are not specifically limited herein. Correspondingly, a width size of the bonding-pad component 10 formed between the inner contour of the recess and the outer contour of the recess is not limited in this embodiment, which may be set according to a specific shape and a specific contour radian. The thickness, perpendicular to the plane direction, of the inward recess 30 formed in the bonding-pad component 10 is not limited in this embodiment as long as the effect of offsetting the aligned stresses of the inner contour of the recess and the outer contour of the recess can be achieved. For example, the thickness of the recess 30 perpendicular to the plane direction may be less than the thickness of the bonding-pad component 10, or the thickness of the recess 30 perpendicular to the plane direction may also be equal to the thickness of the bonding-pad component 10. In this embodiment, when the thickness of the recess 30 perpendicular to the plane direction is less than the thickness of the bonding-pad component 10, a specific value of the thickness of the recess 30 perpendicular to the plane direction is not limited. A specific shape of the bonding-pad component 10 is not limited in this embodiment. For example, the bonding-pad component 10 may be disposed symmetrically along a center line in the plane direction, or the bonding-pad component 10 may also be disposed symmetrically along center lines in a plurality of directions in the plane direction respectively, or the bonding-pad component 10 may further be disposed in an irregular shape.

It needs to be noted that in this embodiment, a thickness direction of the bonding pad is perpendicular to the plane direction. In this embodiment, a junction between the arc-shaped inner contour of the recess and the arc-shaped outer contour of the recess may be of an arc shape, or may also be of a small angular shape of a size of the bonding-pad component 10, or may further be of other shapes.

Further, to reduce the preparation complexity of the device and improve the stress offsetting effect in the inner and outer contours of the recess, the above recess 30 penetrates through the bonding-pad component 10 along a direction perpendicular to the plane direction.

It needs to be noted that in this embodiment, the recess 30 penetrates through the bonding-pad component 10 along the direction perpendicular to the plane direction, that is, a side of the inner contour of the recess in the thickness direction of the bonding-pad component 10 is the same as a size of the outer contour of the recess in the thickness direction of the bonding-pad component 10, so that the aligned stresses of the inner contour of the recess and the outer contour of the recess in the bonding-pad component 10 can be further offset.

The lead-wire frame structure for packaging, including the bonding-pad component 10 and the plurality of pin components 20, provided by the embodiment of the present application is applied. The bonding-pad component 10 is provided with the inward recess 30 in the plane direction of the coplane which is formed by the bonding-pad component and the plurality of pin components 20. In the plane direction, the arc-shaped packaging interfaces for offsetting the stresses are formed in an aligned manner on two sides inside the recess 30 and outside the recess 30 in the bonding-pad component 10. In the present application, the bonding-pad component 10 is provided with the inward recess 30 in the plane direction, and the aligned packaging interfaces of the inner contour of the recess and the outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product. In addition, in the present application, the recess 30 penetrates through the bonding-pad component 10 along the direction perpendicular to the plane direction, so that the aligned stress offsetting of the inner contour of the recess and the outer contour of the recess in the bonding-pad component 10 can be further improved.

### Embodiment 2

Referring to FIG. 1, FIG. 1 is a schematic structural diagram of a lead-wire frame structure for packaging according to an embodiment of the present application. A packaged chip may include:
a bonding-pad component 10 and a plurality of pin components 20, where
the bonding-pad component 10 is provided with an inward recess 30 in a plane direction of a coplane which is formed by the bonding-pad component and the plurality of pin components 20;
in the plane direction, arc-shaped packaging interfaces for offsetting stresses are formed in an aligned manner on an inner contour of the recess and an outer contour of the recess in the bonding-pad component 10; and
the bonding-pad component 10 is disposed symmetrically in at least one direction in the plane direction.

It needs to be noted that in this embodiment, the bonding-pad component 10 is disposed symmetrically along the at least one direction in the plane direction, so that a stress offsetting structure of the bonding-pad component 10 can be simpler, thereby simplifying the shape complexity of the bonding-pad component 10 and improving the preparation efficiency.

A specific number of symmetrical center lines of the bonding-pad component 10 disposed symmetrically in the plane direction is not limited in this embodiment. For example, there may be 1 symmetrical center line of the bonding-pad component 10 disposed symmetrically in the plane direction, or there may also be 2 symmetrical center lines of the bonding-pad component 10 disposed symmetrically in the plane direction, or there may further be 4 symmetrical center lines of the bonding-pad component 10 disposed symmetrically in the plane direction. That is, the bonding-pad component 10 is disposed symmetrically in one direction in the plane direction, or the bonding-pad component 10 is disposed symmetrically in two directions in the plane direction, or the bonding-pad component 10 is disposed symmetrically in four directions in the plane direction.

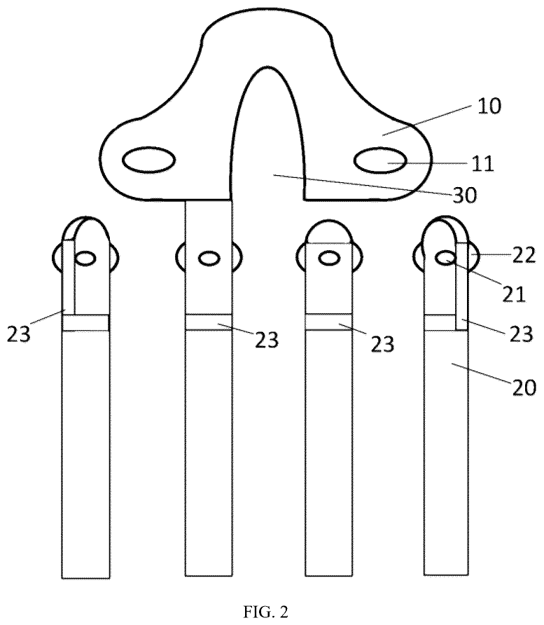

Further, to further reduce the influence of the stresses on the bonding-pad component 10 and reduce the stress effect, the above bonding-pad component 10 is provided with at least one bonding-pad stress relief hole 11; and the bonding-pad stress relief hole 11 is formed symmetrically along the symmetrical center line of the bonding-pad. Specifically, referring to FIG. 2, FIG. 2 is a schematic structural diagram of another lead-wire frame structure for packaging according to an embodiment of the present application.

It needs to be noted that in this embodiment, the bonding-pad stress relief hole 11 is formed in the bonding-pad component 10 along the symmetrical center line in the bonding-pad component 10, so that the stress offsetting effect in the bonding-pad component 10 can be further improved while ensuring the symmetry of the bonding-pad component 10, thereby further reducing the influence of the stresses on the bonding-pad component 10.

A specific number of the bonding-pad stress relief holes 11 formed in the bonding-pad component 10 is not limited in this embodiment. For example, there may be 1 bonding-pad stress relief hole 11 formed in the bonding-pad component 10, or there may also be 2 bonding-pad stress relief holes 11 formed in the bonding-pad component 10, or there may further be 3 bonding-pad stress relief holes 11 formed in the bonding-pad component 10. A specific position where the bonding-pad stress relief hole 11 is formed is not limited in this embodiment as long as the bonding-pad stress relief hole is formed along the symmetrical center line in the bonding-pad component 10. For example, the bonding-pad stress relief hole 11 may be formed at a junction position of a plurality of symmetrical center lines in the bonding-pad component 10, or the bonding-pad stress relief hole 11 may also be formed at other positions in the bonding-pad component 10. A specific shape of the bonding-pad stress relief hole 11 is not limited in this embodiment. For example, the bonding-pad stress relief hole 11 may be formed in a circular shape, or the bonding-pad stress relief hole 11 may also be formed in an elliptical shape, or the bonding-pad stress relief hole 11 may further be formed in other shapes. It needs to be noted that in this embodiment, the specific shape of the bonding-pad stress relief hole 11 may be set according to a specific shape of the bonding-pad component 10, or may also be set according to a width size between the inner and outer contours of the recess in the bonding-pad component 10.

The lead-wire frame structure for packaging, including the bonding-pad component 10 and the plurality of pin components 20, provided by the embodiment of the present application is applied. The bonding-pad component 10 is provided with the inward recess 30 in the plane direction of the coplane which is formed by the bonding-pad component and the plurality of pin components 20. In the plane direction, the arc-shaped packaging interfaces for offsetting the stresses are formed in an aligned manner on two sides inside the recess 30 and outside the recess 30 in the bonding-pad component 10. In the present application, the bonding-pad component 10 is provided with the inward recess 30 in the plane direction, and the aligned packaging interfaces of the inner contour of the recess and the outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product. In this embodiment, the bonding-pad component 10 is disposed symmetrically along the at least one direction in the plane direction, so that the stress offsetting structure of the bonding-pad component 10 can be simpler, thereby simplifying the shape complexity of the bonding-pad component 10 and improving the preparation efficiency. In addition, in the present application, the bonding-pad stress relief hole 11 is formed in the bonding-pad component 10 along the symmetrical center line in the bonding-pad component 10, so that the stress offsetting effect in the bonding-pad component 10 can be further improved while ensuring the symmetry of the bonding-pad component 10, thereby further reducing the influence of the stresses on the bonding-pad component 10.

### Embodiment 3

Referring to FIG. 1, FIG. 1 is a schematic structural diagram of a lead-wire frame structure for packaging according to an embodiment of the present application. A packaged chip may include:
a bonding-pad component 10 and a plurality of pin components 20, where
the bonding-pad component 10 is provided with an inward recess 30 in a plane direction of a coplane which is formed by the bonding-pad component and the plurality of pin components 20;
in the plane direction, arc-shaped packaging interfaces for offsetting stresses are formed in an aligned manner on an inner contour of the recess and an outer contour of the recess in the bonding-pad component 10; and
packaged regions of the plurality of pin components 20 are provided with stress relief through holes 21 along a direction perpendicular to the plane direction.

It needs to be noted that in this embodiment, the plurality of pin components 20 are provided with the stress relief through holes 21 in the packaged regions, thereby further improving the stress offsetting effect between the lead-wire frame structure and a package material. A specific number of the stress relief through holes 21 formed in the packaged region of one pin component 20 along the direction perpendicular to the plane direction is not limited in this embodiment. For example, there may be 1 stress relief through hole 21 formed in the packaged region of one pin component 20 along the direction perpendicular to the plane direction; or there may also be 2 stress relief through holes 21 formed in the packaged region of one pin component 20 along the direction perpendicular to the plane direction; or there may further be 3 stress relief through holes 21 formed in the packaged region of one pin component 20 along the direction perpendicular to the plane direction. A specific shape of the stress relief through hole 21 formed in the packaged region of one pin component 20 along the direction perpendicular to the plane direction is not limited in this embodiment. For example, the stress relief through hole 21 may be of a circular shape, or the stress relief through hole 21 may also be of an elliptical shape, or the stress relief through hole 21 may also be of other shapes, or the stress relief through hole 21 may further be of a combination of a plurality of shapes. When a plurality of stress relief through holes 21 are formed in the packaged region of one pin component 20 along the direction perpendicular to the plane direction, an arrangement manner of the plurality of stress relief through holes 21 in the pin component 20 is not limited in this embodiment. For example, the plurality of stress relief through holes 21 may be arranged along one direction in the plane direction, or the plurality of stress relief through holes 21 may also be formed symmetrically along a symmetrical center line corresponding to the pin component 20, or the plurality of stress relief through holes 21 may further be formed in the pin component 20 along a plurality of layers, that is, the stress relief through hole 21 on an outer side includes the stress relief through hole 21 on an inner side.

Further, to further improve the stress offsetting effect of the lead-wire frame structure, arc-shaped packaging interfaces for offsetting stresses within the stress relief through holes 21 are formed at end portions of the packaged regions of the above plurality of pin components 20 along the plane direction.

Correspondingly, radians of the arc-shaped packaging interfaces formed at the end portions of the packaged regions of the pin components 20 are not limited in this embodiment as long as the stresses within the stress relief through holes 21 can be offset.

Further, to prevent external pollution sources such as impurities and water vapor from intruding into the lead-wire frame structure through an interface formed by the pin components 20 and the package material, widened protruding structures 22 are formed, along a direction perpendicular to an extending direction of the pin components 20 in the plane direction, at the stress relief through holes 21 formed on the above plurality of pin components 20.

It needs to be noted that in this embodiment, the widened protruding structures 22 are formed, along the direction perpendicular to the extending direction of the pin components 20 in the plane direction, at the stress relief through holes 21 formed on the plurality of pin components 20, that is, the widened protruding structures 22 are formed, along a perpendicular direction of the interface formed by the pin components 20 and the package material in the plane direction, at the stress relief through holes 21 formed on the plurality of pin components 20, so that the pollution sources can be prevented from intruding into the lead-wire frame structure along the formed interface.

A specific shape of the widened protruding structure 22 is not limited in this embodiment as long as the pollution sources can be prevented from intruding into the lead-wire frame structure along the formed interface. For example, the widened protruding structure 22 may be of an arc-shaped structure, or the widened protruding structure 22 may also be of structures of other shapes. A specific number of the widened protruding structures 22 is not limited in this embodiment. For example, there may be 1 widened protruding structure 22, or there may also be a plurality of widened protruding structures 22. A setting basis for the number of the widened protruding structures 22 is not limited in this embodiment. For example, the number of the widened protruding structures 22 may be set according to the number of the stress relief through holes 21 in the pin components 20, which may be the same as the number of the stress relief through holes 21, or the number of the widened protruding structures 22 may be set in a customized manner.

Further, to further reduce the influence of the stresses on the lead-wire frame structure, arc-shaped packaging interfaces for offsetting the stresses within the stress relief through holes 21 are formed on the above widened protruding structures 22 along the plane direction.

It needs to be noted that in this embodiment, the widened protruding structures 22 are configured to be the arc-shaped packaging interfaces for offsetting the stresses within the stress relief through holes 21 along the plane direction, so that the stresses formed between the widened protruding structures 22 and the stress relief through holes 21 can be offset. Correspondingly, a specific radian of the arc-shaped packaging interface of the widened protruding structure 22 is not limited in this embodiment as long as the stresses within the stress relief through holes 21 can be offset.

The lead-wire frame structure for packaging, including the bonding-pad component 10 and the plurality of pin components 20, provided by the embodiment of the present application is applied. The bonding-pad component 10 is provided with the inward recess 30 in the plane direction of the coplane which is formed by the bonding-pad component and the plurality of pin components 20. In the plane direction, the arc-shaped packaging interfaces for offsetting the stresses are formed in an aligned manner on two sides inside the recess 30 and outside the recess 30 in the bonding-pad component 10. In the present application, the bonding-pad component 10 is provided with the inward recess 30 in the plane direction, and the aligned packaging interfaces of the inner contour of the recess and the outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product. In addition, in the present application, the plurality of pin components 20 are provided with the stress relief through holes 21 in the packaged regions, thereby further improving the stress offsetting effect between the lead-wire frame structure and a package material. In addition, in the present application, the arc-shaped packaging interfaces for offsetting the stresses within the stress relief through holes 21 are formed at the end portions of the packaged regions of the plurality of pin components 20 along the plane direction, thereby further improving the stress offsetting effect of the lead-wire frame structure; the widened protruding structures 22 are formed, along the direction perpendicular to the extending direction of the pin components 20 in the plane direction, at the stress relief through holes 21 formed on the plurality of pin components 20, so that the external impurities can be prevented from intruding into the lead-wire frame structure; and the arc-shaped packaging interfaces for offsetting the stresses within the stress relief through holes 21 are formed on the widened protruding structures 22 along the plane direction, thereby further reducing the influence of the stresses on the lead-wire frame structure.

### Embodiment 4

Referring to FIG. 1, FIG. 1 is a schematic structural diagram of a lead-wire frame structure for packaging according to an embodiment of the present application. A packaged chip may include:
a bonding-pad component 10 and a plurality of pin components 20, where
the bonding-pad component 10 is provided with an inward recess 30 in a plane direction of a coplane which is formed by the bonding-pad component and the plurality of pin components 20;
in the plane direction, arc-shaped packaging interfaces for offsetting stresses are formed in an aligned manner on an inner contour of the recess and an outer contour of the recess in the bonding-pad component 10; and
end portion packaged regions of the plurality of pin components 20 are provided with micro-etching trenches 23 for preventing intrusion of impurities along an extending direction of the pin components 20.

It needs to be noted that at an interface formed by the pin components 20 and a package material, external pollution sources such as the impurities and water vapor are prone to intrusion into the lead-wire frame structure through the interface. The end portion packaged regions of the pin components 20 are provided with the micro-etching trenches 23, so that the intrusion of the impurities along the extending direction of the pin components 20 can be prevented. A specific shape of the micro-etching trench 23 formed in the pin component 20 is not limited in this embodiment as long as a height difference is formed along a radial direction of the pin component 20, and the intrusion of the impurities can be prevented. For example, the micro-etching trench 23 may be of a rectangular shape, or the micro-etching trench 23 may also be of a cylindrical shape, or the micro-etching trench 23 may further be of a combination of a plurality of shapes. An arrangement manner of the micro-etching trenches 23 in the end portion packaged regions of the pin components 20 is not limited in this embodiment. For example, a plurality of micro-etching trenches 23 that are separated from each other may be formed on the end portion packaged regions of the pin components 20, or one micro-etching trench 23 that is communicated may also be formed on the end portion packaged regions of the pin components 20.

The lead-wire frame structure for packaging, including the bonding-pad component 10 and the plurality of pin components 20, provided by the embodiment of the present application is applied. The bonding-pad component 10 is provided with the inward recess 30 in the plane direction of the coplane which is formed by the bonding-pad component and the plurality of pin components 20. In the plane direction, the arc-shaped packaging interfaces for offsetting the stresses are formed in an aligned manner on two sides inside the recess 30 and outside the recess 30 in the bonding-pad component 10. In the present application, the bonding-pad component 10 is provided with the inward recess 30 in the plane direction, and the aligned packaging interfaces of the inner contour of the recess and the outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product. In addition, in the present application, the recess 30 penetrates through the bonding-pad component 10 along the direction perpendicular to the plane direction, so that the aligned stress offsetting of the inner contour of the recess and the outer contour of the recess in the bonding-pad component 10 can be further improved. The end portion packaged regions of the pin components 20 are provided with the micro-etching trenches 23, so that the intrusion of the impurities along the extending direction of the pin components 20 can be prevented.

For ease of easier understanding of the present application, the above lead-wire frame structure for packaging may specifically be applied to a package structure of an in-line Hall current sensor and may include:
a bonding-pad component 10 and a plurality of pin components 20, where
the bonding-pad component 10 is provided with an inward recess 30 in a plane direction of a coplane which is formed by the bonding-pad component and the plurality of pin components 20; and the recess 30 penetrates through the bonding-pad component 10 along a direction perpendicular to the plane direction;
the bonding-pad component 10 is disposed symmetrically in at least one direction in the plane direction; the bonding-pad component 10 is provided with at least one bonding-pad stress relief hole; and the bonding-pad stress relief hole is formed symmetrically along a symmetrical center line of a bonding pad;
in the plane direction, arc-shaped packaging interfaces for offsetting stresses are formed in an aligned manner on an inner contour of the recess and an outer contour of the recess in the bonding-pad component 10;
packaged regions of the plurality of pin components 20 are provided with stress relief through holes 21 along a direction perpendicular to the plane direction; and arc-shaped packaging interfaces for offsetting stresses within the stress relief through holes 21 are formed at end portions of the packaged regions of the plurality of pin components 20 along the plane direction;
widened protruding structures 22 are formed, along a direction perpendicular to a pin extending direction in the plane direction, at the stress relief through holes 21 formed on the plurality of pin components 20; and arc-shaped packaging interfaces for offsetting the stresses within the stress relief through holes 21 are formed on the widened protruding structures 22 along the plane direction; and
end portion packaged regions of the plurality of pins are provided with micro-etching trenches 23 for preventing intrusion of impurities along the pin extending direction.

The following introduces a sensor package structure provided by an embodiment of the present application, and the sensor package structure described below and the lead-wire frame structure for packaging described above may refer to each other.

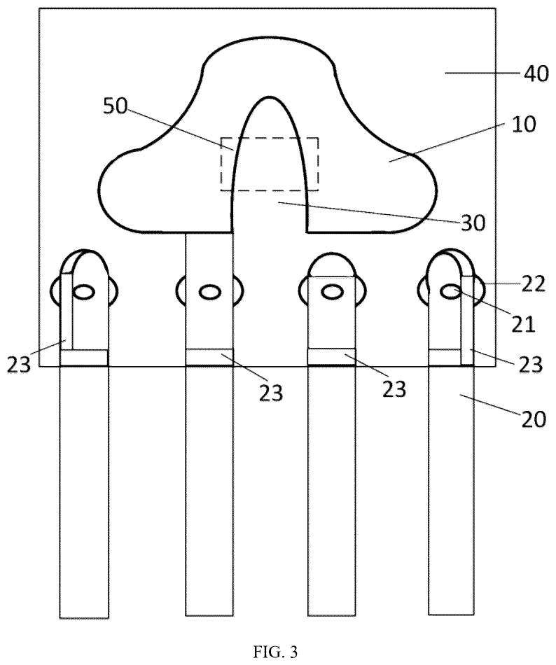

Specifically, referring to FIG. 3, FIG. 3 is a schematic diagram of a sensor package structure according to an embodiment of the present application, which may include:
the above lead-wire frame structure for packaging, a sensor chip 50, and a package body 40, where
the package body 40 is used for packaging the lead-wire frame structure and the sensor chip 50.

It needs to be noted that in this embodiment, the sensor chip 50 may be connected to the bonding-pad component 10 in the lead-wire frame structure or may also form a height difference with the bonding-pad component 10 in the lead-wire frame structure, and may be disposed according to an actual structure of a sensor. In this embodiment, the lead-wire frame structure and the sensor chip 50 may be packaged by using a molding material.

Especially, a loading manner for the sensor chip 50 is designed. In the present application, the sensor chip 50 may be designed to be loaded and fixed at symmetrical positions along the symmetrical center line of the bonding-pad component 10. Compared with a traditional design of multi-contact points (generally three positions), the loading manner at the symmetrical positions along the symmetrical center line of the bonding-pad component 10 can balance and offset a stress of the chip, thereby further reducing an overall structural stress. A specific contact point between the sensor chip 50 and the bonding-pad component 10 is not limited in this embodiment as long as the contact point is distributed symmetrically along the symmetrical center line of the bonding-pad component 10. For example, there may be 2 contact points between the sensor chip 50 and the bonding-pad component 10.

The sensor package structure, at least including the bonding-pad component 10, the plurality of pin components 20, the sensor chip 50, and the package body 40, provided by the embodiment of the present application is applied. The bonding-pad component 10 is provided with the inward recess 30 in the plane direction of the coplane which is formed by the bonding-pad component and the plurality of pin components 20. In the plane direction, the arc-shaped packaging interfaces for offsetting the stresses are formed in an aligned manner on two sides inside the recess 30 and outside the recess 30 in the bonding-pad component 10. The package body 40 is used for packaging the lead-wire frame structure and the sensor chip 50. In the present application, the bonding-pad component 10 is provided with the inward recess 30 in the plane direction, and the aligned packaging interfaces of the inner contour of the recess and the outer contour of the recess are designed to be of arc-shaped structures, which can offset internal and external stresses, such that stresses having equal magnitudes and opposite directions are generated at an internal interface and an external interface, where a molding body and a frame, which have been subjected to packaging, are in contact with each other; and by means of offsetting the stresses at the interfaces, a whole package structure is enabled to be in a stress balance state in a temperature-changing environment, and is not prone to interface delamination or structural deformation, thereby improving the stability of a product.

Various embodiments in the specification are described in a progressive manner, and each embodiment focuses on the differences from the other embodiments, and the same or similar parts between the various embodiments can refer to each other.

Finally, it needs to further be noted that relational terms herein, such as first and second, are only used to distinguish one entity or operation from another entity or operation, and do not necessarily require or imply any such actual relationship or order among these entities or operations. In addition, the terms “include”, “comprise”, or any other variants thereof are intended to cover non-exclusive inclusion.

The lead-wire frame structure for packaging and the sensor package structure that are provided by the present application are described above in detail. The present application is elaborated by applying a plurality of specific examples. The descriptions of the above embodiments are only used to help understand the method and its core idea of the present application; meanwhile, according to the idea of the present application, there will be changes in the specific implementations and the application scope for those of ordinary skill in the art. In summary, the content of the specification should not be understood as a limitation to the present application.

What is claimed is:

1. A lead-wire frame structure for packaging, comprising:
a bonding-pad component and a plurality of pin components, wherein
the bonding-pad component is provided with an inward recess in a plane direction of a coplane which is formed by the bonding-pad component and the plurality of pin components;
in the plane direction, arc-shaped packaging interfaces for offsetting stresses are formed in an aligned manner on an inner contour of the recess and an outer contour of the recess in the bonding-pad component;
the outer contour of the recess comprises two first arcs in opposite directions to the recess and second arcs connected to the first arcs; and the second arcs are in the same directions as the recess; and
in the bonding-pad component, the first arcs are disposed on two sides of the recess respectively.

2. The lead-wire frame structure for packaging according to claim 1, wherein the bonding-pad component is disposed symmetrically in at least one direction in the plane direction.

3. The lead-wire frame structure for packaging according to claim 1, wherein the recess penetrates through the bonding-pad component along a direction perpendicular to the plane direction.

4. The lead-wire frame structure for packaging according to claim 1, wherein packaged regions of the plurality of pin components are provided with stress relief through holes along a direction perpendicular to the plane direction.

5. The lead-wire frame structure for packaging according to claim 4, wherein arc-shaped packaging interfaces for offsetting stresses within the stress relief through holes are formed at end portions of the packaged regions of the plurality of pin components along the plane direction.

6. The lead-wire frame structure for packaging according to claim 5, wherein widened protruding structures are formed, along a direction perpendicular to an extending direction of the pin components in the plane direction, at the stress relief through holes formed on the plurality of pin components.

7. The lead-wire frame structure for packaging according to claim 6, wherein arc-shaped packaging interfaces for offsetting the stresses within the stress relief through holes are formed on the widened protruding structures along the plane direction.

8. The lead-wire frame structure for packaging according to claim 1, wherein end portion packaged regions of the plurality of pin components are provided with micro-etching trenches for preventing intrusion of impurities along an extending direction of the pin components.

9. The lead-wire frame structure for packaging according to claim 2, wherein the bonding-pad component is provided with at least one bonding-pad stress relief hole; and
the bonding-pad stress relief hole is formed symmetrically along a symmetrical center line of a bonding pad.

10. A sensor package structure, comprising:
the lead-wire frame structure for packaging according to claim 1, a sensor chip, and a package body, wherein
the package body is used for packaging the lead-wire frame structure and the sensor chip.
